(19) United States
(12) Patent Application Publication
(10) Pub. No.: US 2019/0267928 A1
(43) Pub. Date: Aug. 29, 2019

(54) SOLAR POWER ABSORBING ARTIFICIAL TURF

(71) Applicant: Charles Favroth, Antioch, CA (US)

(72) Inventor: Charles Favroth, Antioch, CA (US)

(21) Appl. No.: 16/286,572

(22) Filed: Feb. 26, 2019

Related U.S. Application Data
(60) Provisional application No. 62/635,463, filed on Feb. 26, 2018.

(51) Int. Cl. H02S 10/20; H01L 27/30; H02S 20/10; H01L 31/048

(52) U.S. Cl. CPC H02S 10/20; H01L 31/0481; H02S 20/10; H01L 27/301

(57) ABSTRACT

A solar energy absorbing artificial turf is presented. The artificial turf includes a durable and flexible solar energy absorbing base. The base is made of elastic and resilient material and one or more photovoltaic cells. The artificial turf also includes a plurality of colored synthetic fiber strands coupled to the surface of the solar energy absorbing base. The plurality of colored synthetic fiber strands are made of light transparent or semi-transparent synthetic material.

### CROSS-REFERENCE TO RELATED APPLICATIONS

The present invention claims priority to co-pending provisional U.S. patent application No. 62/635,463, filed Feb. 26, 2018, which is incorporated herein by reference in its entirety.

### TECHNICAL FIELD

The present disclosure relates generally to artificial turf.

### BACKGROUND

Artificial turf is a surface of synthetic fibers made to look like natural grass. It is most often used in arenas for sports that were originally or are normally played on grass. However, it is now being used on residential lawns and commercial applications as well. One of the main benefits of artificial turf is maintenance—artificial turf stands up to heavy use, such as in sports, and requires no irrigation or trimming. Domed, covered, and partially covered stadiums may require artificial turf because of the difficulty of getting grass enough sunlight to stay healthy. Artificial turf also has many disadvantages: limited life, periodic cleaning requirements, petroleum use, toxic chemicals from infill, and heightened health and safety concerns. However, due to its synthetic nature, artificial turf can be enhanced and modified to provide even greater benefits. Thus, the present disclosure provides an improved artificial turf capable of absorbing solar power.

### SUMMARY

The following presents a simplified summary of the disclosure in order to provide a basic understanding of certain embodiments of the present disclosure. This summary is not an extensive overview of the disclosure and it does not identify key/critical elements of the present disclosure or delineate the scope of the present disclosure. Its sole purpose is to present some concepts disclosed herein in a simplified form as a prelude to the more detailed description that is presented later.

A solar energy absorbing artificial turf is presented. The artificial turf includes a durable and flexible solar energy absorbing base. The base is made of elastic and resilient material and one or more photovoltaic cells. The artificial turf also includes a plurality of colored synthetic fiber strands coupled to the surface of the solar energy absorbing base. The plurality of colored synthetic fiber strands are made of light transparent or semi-transparent synthetic material.

Another aspect of the present disclosure includes a method for manufacturing solar energy absorbing artificial turf. The method comprises adding light transparent or semi-transparent coloring to light transparent or semi-transparent plastic pellets. Next, plastic pellets are melted into a cohesive amalgam. Then, the amalgam is extruded through steel plates with holes thereby creating strands of colored fibers. Next, the method includes cooling and solidifying the strands of colored fibers with water. Then, the solidified strands of colored fibers are pulled through a machine comb structure. Then, the strands of colored fibers are stretched via rowers and spooled. Next, individual strands are combined to form multi-ply, synthetic yarn. Then, the yarn is looped via a tufting machine through a mesh fabric and sheeting material combination. Last, the looped yarn is cut thereby giving the appearance of grass.

Yet another aspect of the present disclosure includes a field. The field comprises one or more artificial turf panels. Each artificial turf panel includes a durable and flexible solar energy absorbing base. The base is made of elastic and resilient material and one or more photovoltaic cells. Each artificial turf panel also includes a plurality of colored synthetic fiber strands coupled to the surface of the solar energy absorbing base. The plurality of colored synthetic fiber strands are made of light transparent or semi-transparent synthetic material.

These and other embodiments are described further below with reference to the figures.

### BRIEF DESCRIPTION OF THE DRAWINGS

The disclosure may best be understood by reference to the following description taken in conjunction with the accompanying drawings, which illustrate particular embodiments of the present disclosure.

FIG. 1A illustrates a side view of blades of UV transparent turf, in accordance with one or more embodiments of the present disclosure.

FIG. 1B illustrates a side view of a mesh layer including uncut UV transparent strands sewn therein, in accordance with one or more embodiments of the present disclosure.

FIG. 1C illustrates a side view of low profile solar cells, in accordance with one or more embodiments of the present disclosure.

FIG. 2 illustrates an aerial view of a layout of solar turf rows with connections for distribution of collected energy, in accordance with one or more embodiments of the present disclosure.

FIG. 3 illustrates a mesh layer design showing contact points with solar panels, in accordance with one or more embodiments of the present disclosure.

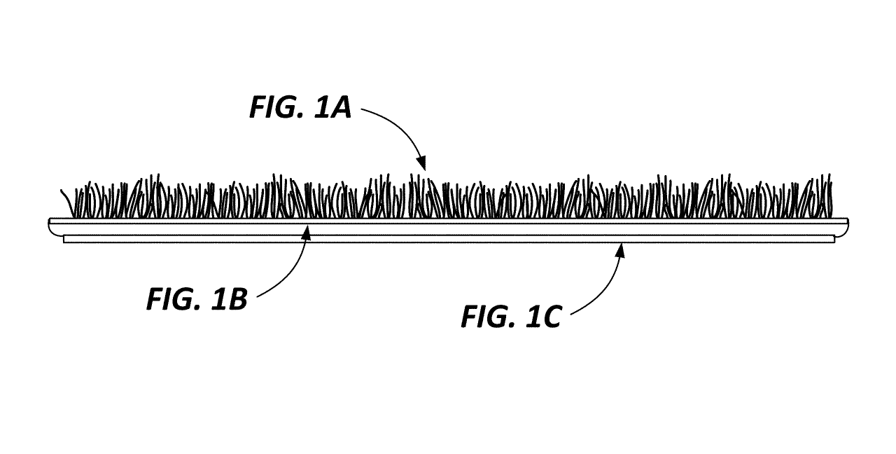

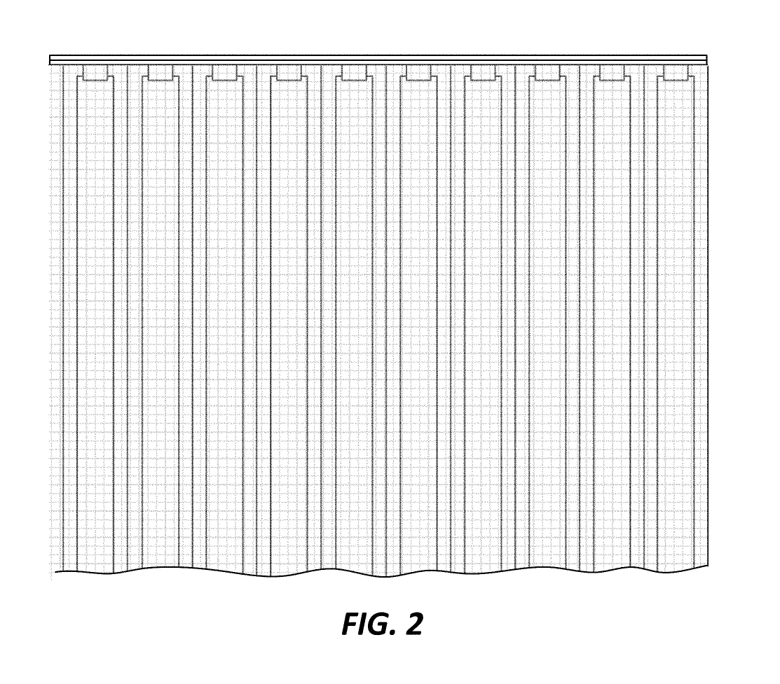

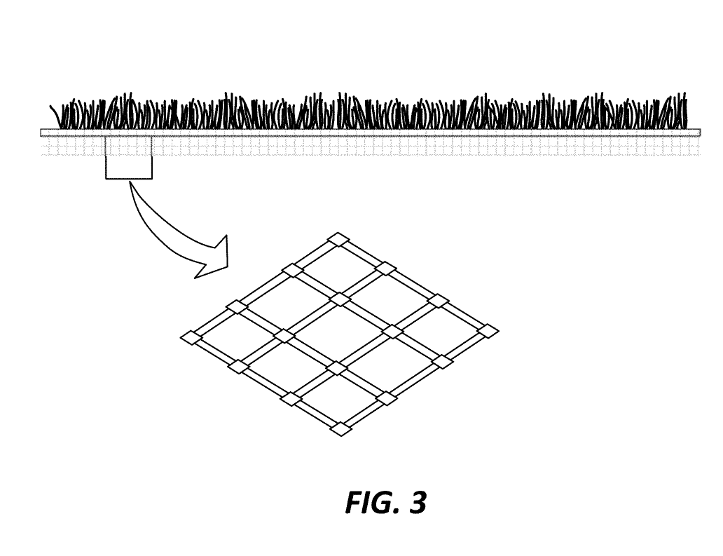

Like reference numerals refer to corresponding parts throughout the drawings.

### DETAILED DESCRIPTION OF PARTICULAR EMBODIMENTS

Reference will now be made in detail to some specific examples of the present disclosure including the best modes contemplated by the inventors for carrying out the present disclosure. Examples of these specific embodiments are illustrated in the accompanying drawings. While the present disclosure is described in conjunction with these specific embodiments, it will be understood that it is not intended to limit the present disclosure to the described embodiments. On the contrary, it is intended to cover alternatives, modifications, and equivalents as may be included within the spirit and scope of the present disclosure as defined by the appended claims.

In the following description, numerous specific details are set forth in order to provide a thorough understanding of the present disclosure. Particular example embodiments of the present disclosure may be implemented without some or all of these specific details. In other instances, well known process operations have not been described in detail in order not to unnecessarily obscure the present disclosure.

Various techniques and mechanisms of the present disclosure will sometimes be described in singular form for clarity. However, it should be noted that some embodiments include multiple iterations of a technique or multiple instantiations of a mechanism unless noted otherwise. Furthermore, the techniques and mechanisms of the present disclosure will sometimes describe a connection between two entities. It should be noted that a connection between two entities does not necessarily mean a direct, unimpeded connection, as a variety of other entities may reside between the two entities. For example, a fiber strand being coupled to a base does not necessarily mean there are no other components or materials in between the coupling. Consequently, a connection does not necessarily mean a direct, unimpeded connection unless otherwise noted.

A solar energy absorbing artificial turf is presented herein. The artificial turf includes light transparent synthetic fiber strands coupled to a durable and flexible photovoltaic base.

In some embodiments, the turf is composed of a proprietary composition of microfilament polyethylene photosynthetic chemical blend fibers ranging in classification levels from very-low-density to medium density polyethylene. This range directly determines the light composition. In some embodiments, the fibers are tufted into a polypropylene, polystyrene, or acrylic backing. In some embodiments, the fiber strands are coupled to Full-Spectrum Photovoltaic material. In some embodiments, the photovoltaic material includes thin-film solar cells, which can include semi-conductor material made of a combination of indium, gallium and nitrogen.

Polyethylene is of low strength, hardness and rigidity, but has a high ductility and impact strength as well as low friction. It shows strong creep under persistent force, which can be reduced by addition of short fibers. It feels waxy when touched.

The usefulness of polyethylene is limited by its melting point of 80° C. (176° F.) (HDPE, types of low crystalline softens earlier). For common commercial grades of medium- and high-density polyethylene the melting point is typically in the range 120 to 180° C. (248 to 356° F.). The melting point for average, commercial, low-density polyethylene is typically 105 to 115° C. (221 to 239° F.). These temperatures vary strongly with the type of polyethylene.

Polyethylene consists of nonpolar, saturated, high molecular weight hydrocarbons. Therefore, its chemical behavior is similar to paraffin. The individual macromolecules are not covalently linked. Because of their symmetric molecular structure, they tend to crystallize; overall polyethylene is partially crystalline Higher crystallinity increases density and mechanical and chemical stability.

Most LDPE, MDPE, and HDPE grades have excellent chemical resistance, meaning they are not attacked by strong acids or strong bases, and are resistant to gentle oxidants and reducing agents. Crystalline samples do not dissolve at room temperature. Polyethylene (other than cross-linked polyethylene) usually can be dissolved at elevated temperatures in aromatic hydrocarbons such as toluene or xylene, or in chlorinated solvents such as trichloroethane or trichlorobenzene.

Polyethylene absorbs almost no water. The gas and water vapor permeability (only polar gases) is lower than for most plastics; oxygen, carbon dioxide and flavorings on the other hand can pass it easily.

Polyethylene burns slowly with a blue flame having a yellow tip and gives off an odor of paraffin (similar to candle flame). The material continues burning on removal of the flame source and produces a drip.

Polyethylene cannot be imprinted or stuck together without pretreatment.

Polyethylene is a good electrical insulator. It offers good tracking resistance; however, it becomes easily electrostatically charged (which can be reduced by additions of graphite, carbon black or antistatic agents).

Depending on thermal history and film thickness PE can vary between almost clear (transparent), milky-opaque (translucent) or opaque. LDPE thereby owns the greatest, LLDPE slightly less and HDPE the least transparency. Transparency is reduced by crystallites if they are larger than the wavelength of visible light.

While the present disclosure has been particularly shown and described with reference to specific embodiments thereof, it will be understood by those skilled in the art that changes in the form and details of the disclosed embodiments may be made without departing from the spirit or scope of the present disclosure. It is therefore intended that the present disclosure be interpreted to include all variations and equivalents that fall within the true spirit and scope of the present disclosure. Although many of the components and processes are described above in the singular for convenience, it will be appreciated by one of skill in the art that multiple components and repeated processes can also be used to practice the techniques of the present disclosure.

What is claimed is:

1. An artificial turf comprising:
a durable and flexible solar energy absorbing base, the base comprising elastic and resilient material and one or more photovoltaic cells; and
a plurality of colored synthetic fiber strands coupled to the surface of the solar energy absorbing base, the plurality of colored synthetic fiber strands comprising light transparent or semi-transparent synthetic material.

2. The artificial turf of claim 1, wherein the colored synthetic fiber strands comprise microfilament polyethylene photosynthetic chemical blend fibers.

3. The artificial turf of claim 2, wherein the chemical blend fibers range from very-low-density to high density polyethylene.

4. The artificial turf of claim 3, wherein the range of low-density to high density polyethylene includes one or more of the following: Ultra-High Molecular Weight Polyethylene (UHMWPE), High Density Polyethylene (HDPE), Cross-linked polyethylene (PEX or XLPE), Medium-Density polyethylene (MDPE), Linear low-density polyethylene (LLDPE), Low-density polyethylene (LDPE), and Very-low-density polyethylene (VLDPE).

5. The artificial turf of claim 1, wherein the solar energy absorbing base comprises full-spectrum thin-film photovoltaic cells.

6. The artificial turf of claim 5, wherein the full-spectrum thin-film photovoltaic cells comprise a semi-conductor material made of a combination of indium, gallium, and nitrogen.

7. A method for manufacturing solar energy absorbing artificial turf comprising:
adding light transparent or semi-transparent coloring to light transparent or semi-transparent plastic pellets;
melting the plastic pellets into a cohesive amalgam;
extruding the amalgam through steel plates with holes thereby creating strands of colored fibers;
cooling and solidifying the strands of colored fibers with water;
pulling the solidified strands of colored fibers through a machine comb structure;
stretching the strands of colored fibers via rowers;
spooling the strands of colored fibers;
combining individual strands to form multi-ply, synthetic yarn;
looping the yarn via a tufting machine through a mesh fabric and sheeting material combination; and
cutting the looped yarn thereby giving the appearance of grass.

8. A field comprising:
one or more artificial turf panels, each panel comprising:
a durable and flexible solar energy absorbing base, the base comprising elastic and resilient material and one or more photovoltaic cells; and
a plurality of colored synthetic fiber strands coupled to the surface of the solar energy absorbing base, the plurality of colored synthetic fiber strands comprising light transparent or semi-transparent synthetic material.
